(19) United States
(12) Patent Application Publication
(10) Pub. No.: US 2005/0213302 A1
(43) Pub. Date: Sep. 29, 2005

(54) Heat-dissipating device for a portable computer

(76) Inventor: Hao-Cheng Lin, Taipei City (TW)

Correspondence Address: DLA PIPER RUDNICK GRAY CARY US, LLP, 2000 UNIVERSITY AVENUE, E. PALO ALTO, CA, 94303-2248, US

(21) Appl. No.: 10/812,592

(22) Filed: Mar. 29, 2004

(51) Int. Cl. H05K 7/20

(52) U.S. Cl. 361/695

(57) ABSTRACT

A heat-dissipating device is adapted for use with a portable computer that includes a host module and a display module connected pivotally to the host module. The heat-dissipating device includes a support member and a fan unit. The support member includes a box body having a bottom wall and a peripheral wall that extends upwardly from a periphery of the bottom wall. The box body is formed with an air inlet and an air outlet. The peripheral wall is adapted to support the host module of the portable computer thereon. The fan unit is mounted on the box body, and is operable so as to draw air into the box body through the air inlet and so as to discharge the air in the box body through the air outlet.

### BACKGROUND OF THE INVENTION

1. Field of the Invention

The invention relates to a heat-dissipating device, more particularly to a heat-dissipating device for a portable computer.

2. Description of the Related Art

A conventional portable computer includes a host module and a display module connected pivotally to the host module. The host module usually has a housing that is made of a metal alloy with good heat-dissipating characteristics, such as an alloy of magnesium and aluminum, and that has components, such as a keyboard, a motherboard, a hard disk drive, etc., mounted thereon. The display module is provided with a liquid crystal display (LCD) screen. With the increase in the operating speed of the central processing unit (CPU) on the motherboard, the power consumption of the components on the housing of the host module has also increased considerably in recent years, which results in a high temperature inside the housing of the host module after a period of use. Particularly, under normal room temperature conditions, the temperature inside the host module of a portable computer that is not installed with a dedicated heat-dissipating device can reach as high as 46° C. On the other hand, while the temperature inside the host module can be lowered down to 43° C. when a dedicated heat-dissipating device is installed therein, it is still inadequate to prevent malfunctioning of the portable computer due to overheating. Hence, the heat-dissipating effect of the host module of the portable computer is a critical issue that cannot be neglected by the computer industry.

### SUMMARY OF THE INVENTION

Therefore, the object of the present invention is to provide a heat-dissipating device for a portable computer that can overcome the aforesaid drawback of the prior art.

According to the present invention, a heat-dissipating device is adapted for use with a portable computer that includes a host module and a display module connected pivotally to the host module. The heat-dissipating device comprises a support member and a fan unit. The support member includes a box body having a bottom wall and a peripheral wall that extends upwardly from a periphery of the bottom wall. The box body is formed with an air inlet and an air outlet. The peripheral wall is adapted to support the host module of the portable computer thereon. The fan unit is mounted on the box body, and is operable so as to draw air into the box body through the air inlet and so as to discharge the air in the box body through the air outlet.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of the first preferred embodiment of a heat-dissipating device for a portable computer according to the present invention;

FIG. 2 is a sectional view of the first preferred embodiment when used to dissipate heat generated by a portable computer;

FIG. 3 is a perspective view of the second preferred embodiment of a heat-dissipating device for a portable computer according to the present invention;

FIG. 4 is a schematic electrical circuit diagram of a detecting circuit of the second preferred embodiment; and

FIG. 5 is a perspective view of the third preferred embodiment of a heat-dissipating device for a portable computer according to the present invention.

### DETAILED DESCRIPTION OF THE PREFERRED EMBODIMENTS

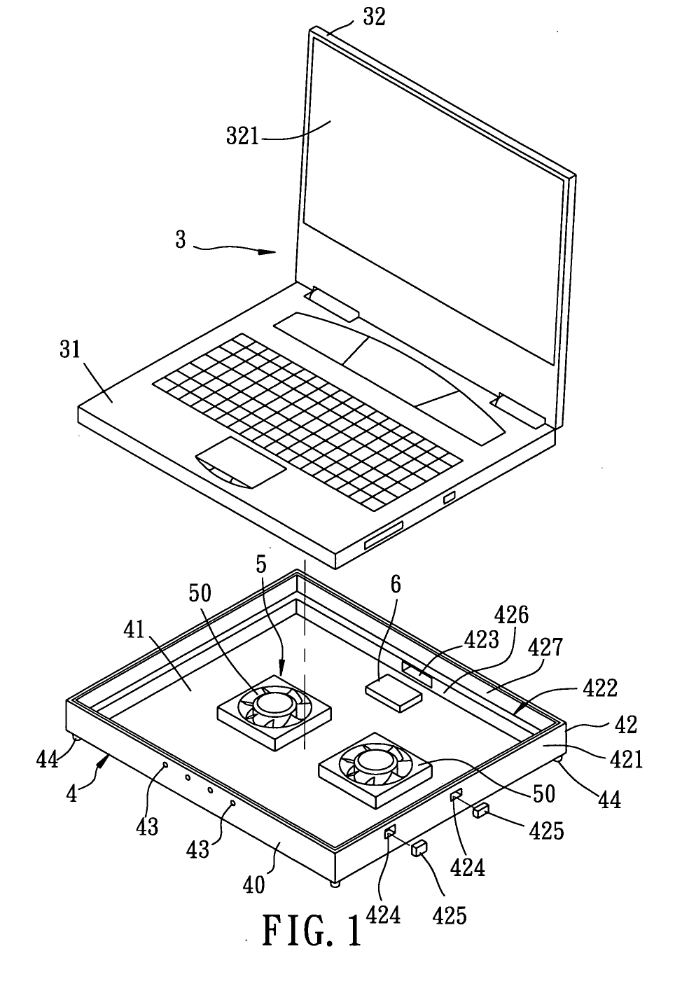

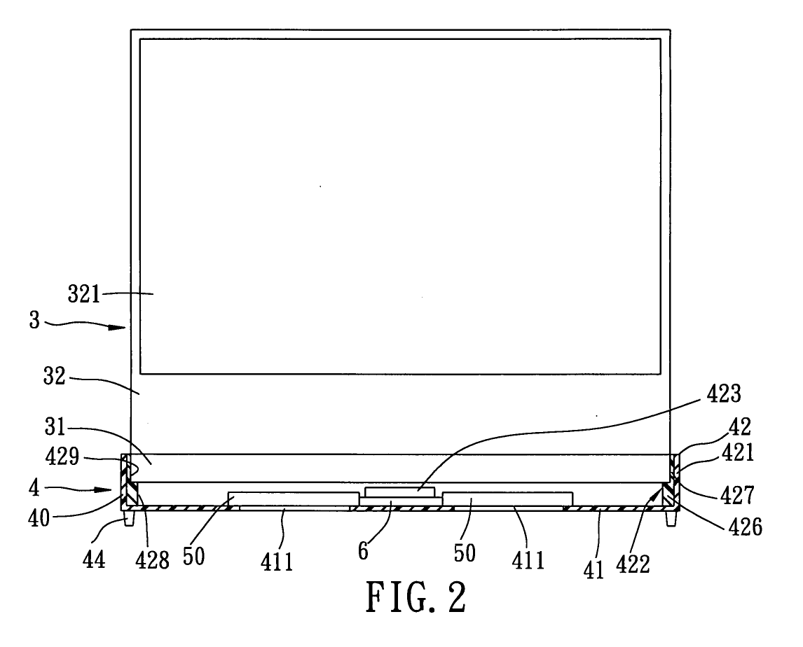

Referring to FIGS. 1 and 2, the first preferred embodiment of a heat-dissipating device according to the present invention is shown to be adapted for use with a portable computer 3 that includes a host module 31 and a display module 32 connected pivotally to the host module 31 and provided with a liquid crystal display (LCD) screen 321. The heat-dissipating device of this embodiment includes a support member 4, a fan unit 5, and a fragrance dispenser 6.

The support member 4 includes a rectangular box body 40 having a bottom wall 41 and a peripheral wall 42 that extends upwardly from a periphery of the bottom wall 41. The peripheral wall 42 is adapted to support the host module 31 of the portable computer 3 thereon. The support member 4 further includes a set of foot posts 44 mounted on the bottom wall 41 of the box body 40. In this embodiment, the bottom wall 41 of the box body 40 is formed with a pair of air inlets 411. The peripheral wall 42 includes an outer wall portion 421 extending integrally from the bottom wall 41, and an inner wall portion 422 fitted in the outer wall portion 421. Preferably, the inner wall portion 422 is made of a foamed plastic material, and has a thicker lower section 426 and a thinner upper section 427, thereby configuring the box body 40 with a lower receiving space 428 proximate to the bottom wall 41, and an upper receiving space 429 in spatial communication with the lower receiving space 428 and larger than the lower receiving space 428. Particularly, the upper receiving space 429 has dimensions sufficient to receive the host module 31 of the portable computer 3 fittingly therein, as best shown in FIG. 2. In this embodiment, the depth of the upper receiving space 429 corresponds to the thickness of the host module 31 of the portable computer 3. The peripheral wall 42 is further formed with an air outlet 423 that extends through the inner and outer wall portions 422, 421 and that is registered with the lower receiving space 428, and a pair of connector holes 424 that are formed through the inner and outer wall portions 422, 421 and that are registered with the upper receiving space 429. Each of a pair of plugs 425 is fitted removably in a respective one of the connector holes 424. With the provision of the connector holes 424, different cables (not shown), such as a power cord, a mouse cord, etc., can be extended into the box body 40 for connecting with the host module 31 of the portable computer 3. It is noted that the number, locations and sizes of the connector holes 24 can vary depending on actual design requirements.

Preferably, the peripheral wall 42 of the box body 40 has light-emitting components 43 mounted thereon. In practice, the light-emitting components 43 may include a plurality of light emitting diodes (LED) that emit different colors of light and that are activated in sequence to provide a decorative effect.

In this embodiment, the fan unit 5 includes a pair of fans 50, each of which is mounted on the bottom wall 41, is disposed in the box body 40, and is registered with a respective air inlet 411. The fan unit 5 is operable so as to draw air into the box body 40 through the air inlets 411 and so as to discharge the air in the box body 40 through the air outlet 423. It is noted that the number of fans 50 can vary in accordance with actual design requirements.

The fragrance dispenser 6, such as a perfume dispenser, can be mounted anywhere in the box body 40. In this embodiment, the fragrance dispenser 6 is mounted adjacent to the air outlet 423. The fragrance dispenser 6 is an optional accessory of the heat-dissipating device.

In use, the host module 31 of the portable computer 3 is fitted into the upper receiving space 429 of the box body 40 such that the bottom side of the host module 31 is supported by the thicker lower section 426 of the inner wall portion 422 of the peripheral wall 42 of the box body 40. Thereafter, when the fans 50 of the fan unit 5 are activated, cool air is drawn into the box body 40 through the air inlets 411, and hot air is discharged from the box body 40 through the air outlet 423, thereby dissipating heat that is generated by the host module 31 during operation of the portable computer 3. In addition, by virtue of the fragrance dispenser 6 that is mounted in the box body 40, when the hot air flows through the air outlet 423, a fragrant smell will be diffused as well.

Based on actual test results, under normal room temperature conditions, the temperature inside the host module 31 of a portable computer 3 that is not installed with a dedicated heat-dissipating device therein can be lowered from 46° C. to 35° C. when the heat-dissipating device of this invention is in use.

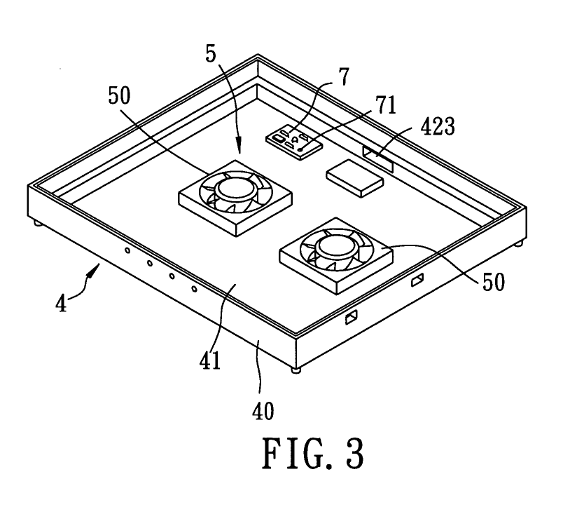

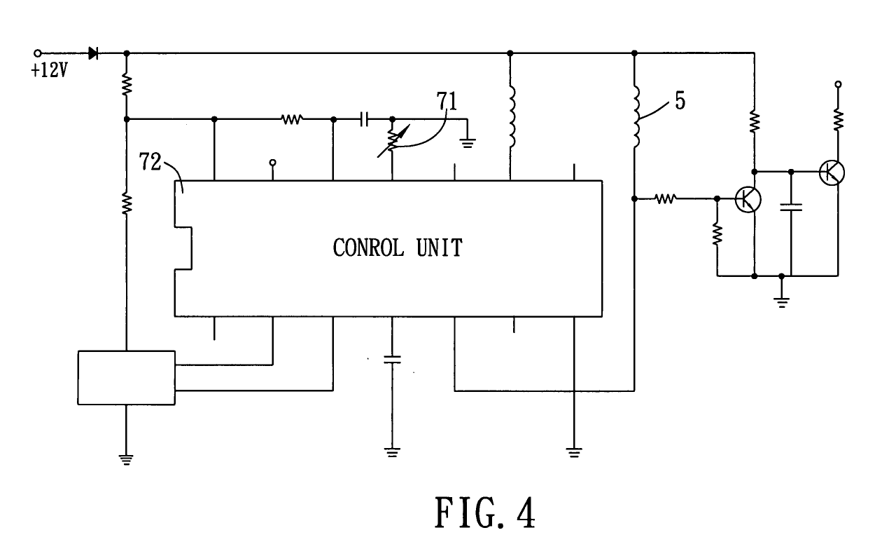

FIGS. 3 and 4 illustrate the second preferred embodiment of a heat-dissipating device for a portable computer according to the present invention. Unlike the first preferred embodiment, the heat-dissipating device of this embodiment further comprises a detecting circuit 7 that is coupled to the fan unit 5 and that is mounted on the bottom wall 41 of the box body 40 adjacent to the air outlet 423. The detecting circuit 7 includes a temperature sensor 71 for detecting the temperature of air in the box body 40, and a control unit 72 in the form of an integrated circuit that is coupled to the temperature sensor 71. In this embodiment, the temperature sensor 71 is a thermistor. The control unit 72 of the detecting circuit 7 is configured to perform different operations according to the temperature detected by the temperature sensor 71. For example, the control unit 72 can be configured to control the fan unit 5 to operate at an operating speed that corresponds to the temperature in the box body 40. That is, the detecting circuit 7 can control the fan unit 5 to increase its operating speed to enhance the heat-dissipating effect when necessary. In addition, the control unit 72 can be configured to generate an audible or visible alarm output when the temperature in the box body 40 exceeds a predetermined threshold.

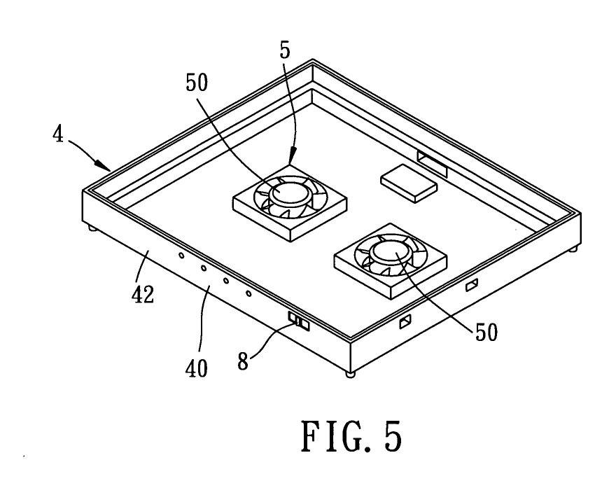

FIG. 5 illustrates the third preferred embodiment of a heat-dissipating device for a portable computer according to the present invention. Unlike the first preferred embodiment, the heat-dissipating device of this embodiment further comprises a control switch 8 mounted on the peripheral wall 42 of the box body 40 and coupled to the fan unit 5. The control switch 8 is operable so as to control operating speed of the fan unit 5.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A heat-dissipating device adapted for use with a portable computer that includes a host module and a display module connected pivotally to the host module, said heat-dissipating device comprising:
a support member including a box body having a bottom wall and a peripheral wall that extends upwardly from a periphery of said bottom wall, said box body being formed with an air inlet and an air outlet, said peripheral wall being adapted to support the host module of the portable computer thereon; and
a fan unit mounted on said box body and operable so as to draw air into said box body through said air inlet and so as to discharge the air in said box body through said air outlet.

2. The heat-dissipating device as claimed in claim 1, wherein said air inlet is formed in said bottom wall of said box body, and said air outlet is formed in said peripheral wall of said box body.

3. The heat-dissipating device as claimed in claim 2, wherein said fan unit is mounted on said bottom wall, is disposed in said box body, and is registered with said air inlet.

4. The heat-dissipating device as claimed in claim 3, wherein said peripheral wall includes an outer wall portion extending from said bottom wall, and an inner wall portion fitted in said outer wall portion, said inner wall portion configuring said box body with a lower receiving space proximate to said bottom wall, and an upper receiving space in spatial communication with said lower receiving space and larger than said lower receiving space,
said upper receiving space having dimensions sufficient to receive the host module of the portable computer fittingly therein.

5. The heat-dissipating device as claimed in claim 4, wherein said air outlet is formed through said inner and outer wall portions and is registered with said lower receiving space.

6. The heat-dissipating device as claimed in claim 4, wherein said box body further has a connector hole that is formed through said inner and outer wall portions and that is registered with said upper receiving space.

7. The heat-dissipating device as claimed in claim 6, further comprising a plug fitted removably in said connector hole.

8. The heat-dissipating device as claimed in claim 1, further comprising a fragrance dispenser mounted in said box body.

9. The heat-dissipating device as claimed in claim 8, wherein said fragrance dispenser is disposed adjacent to said air outlet.

10. The heat-dissipating device as claimed in claim 1, wherein said support member further includes a set of foot posts mounted on said bottom wall of said box body.

11. The heat-dissipating device as claimed in claim 1, further comprising a detecting circuit that includes a temperature sensor for detecting temperature in said box body.

12. The heat-dissipating device as claimed in claim 11, wherein said temperature sensor is a thermistor.

13. The heat-dissipating device as claimed in claim 11, wherein said detecting circuit is coupled to said fan unit and is configured to control operating speed of said fan unit according to the temperature in said box body.

14. The heat-dissipating device as claimed in claim 11, wherein said detecting circuit is configured to generate an alarm output according to the temperature in said box body.

15. The heat-dissipating device as claimed in claim 1, further comprising a control switch mounted on said box body and coupled to said fan unit, said control switch being operable so as to control operating speed of said fan unit.
